(19) United States
(12) Patent Application Publication
(10) Pub. No.: US 2010/0237440 A1
(43) Pub. Date: Sep. 23, 2010

(54) SEMICONDUCTOR DEVICE AND METHOD FOR MANUFACTURING THE SAME

(75) Inventor: Satoru ITO, Hyogo (JP)

Correspondence Address: MCDERMOTT WILL & EMERY LLP, 600 13TH STREET, NW, WASHINGTON, DC, 20005-3096, US

(73) Assignee: Panasonic Corporation, Osaka (JP)

(21) Appl. No.: 12/790,148

(22) Filed: May 28, 2010

Related U.S. Application Data
(63) Continuation of application No. PCT/JP2009/002250, filed on May 21, 2009.

(30) Foreign Application Priority Data
Jul. 7, 2008 (JP) 2008-177080

(51) Int. Cl. H01L 29/78; H01L 21/336

(52) U.S. Cl. 257/408; 438/305; 257/E29.266; 257/E21.409

(57) ABSTRACT

A semiconductor device includes a gate insulating film formed on a semiconductor region of a first conductivity type, a gate electrode formed on the gate insulating film and including a polysilicon film of a second conductivity type and a first silicon mixed crystal layer formed on the polysilicon film, a first silicide layer formed on the first silicon mixed crystal layer, impurity diffused regions of the second conductivity type formed in the semiconductor region laterally outside the gate electrode, second silicon mixed crystal layers containing carbon formed in upper regions of the impurity diffused regions, and second silicide layers formed on the second silicon mixed crystal layers.

### CROSS-REFERENCE TO RELATED APPLICATIONS

This is a continuation of PCT International Application PCT/JP2009/002250 filed on May 21, 2009, which claims priority to Japanese Patent Application No. 2008-177080 filed on Jul. 7, 2008. The disclosures of these applications including the specifications, the drawings, and the claims are hereby incorporated by reference in their entirety.

### BACKGROUND

The present disclosure relates to semiconductor devices and methods for manufacturing the semiconductor devices. More particularly, the present disclosure relates to semiconductor devices including a metal insulator semiconductor field effect transistor (MISFET) having a silicon mixed crystal layer in source/drain regions thereof, and methods for manufacturing the semiconductor devices.

In recent years, in order to improve the drive capability of MISFETs (hereinafter referred to as “MIS transistors”), an attempt has been made to increase the mobility of electrons by applying a stress to the channel region. Here, as a technique of applying a stress to the channel region, a silicon mixed crystal layer containing carbon may be provided in the source/drain regions of an N-type MIS transistor.

A method for manufacturing a conventional semiconductor device will be described hereinafter with reference to FIGS. 6A-6D (see, for example, Y. Liu et al., “Strained Si Channel MOSFETs with Embedded Silicon Carbon Formed by Solid Phase Epitaxy,” 2007 Symposium on VLSI Technology Digest of Technical Papers). FIGS. 6A-6D are cross-sectional views along the gate length for describing main steps in the method for manufacturing the conventional semiconductor device in the order in which the semiconductor device is manufactured.

Initially, as shown in FIG. 6A, an isolation region 101 is formed in an upper portion of a semiconductor substrate 100 made of silicon. As a result, a semiconductor region 100x surrounded by the isolation region 101 is formed in the semiconductor substrate 100. Thereafter, a p-type well region 102 is formed in the semiconductor substrate 100.

Thereafter, a gate insulating film 103, a gate electrode 104, and a cap film 105 are successively formed on the semiconductor region 100x. Thereafter, n-type extension doped regions 106 are formed in the semiconductor region 100x laterally outside the gate electrode 104 (i.e., the n-type extension doped regions 106 are adjacent to the channel region below the gate electrode 104 and extending laterally away from it). Thereafter, a sidewall 108A including an inner sidewall 107 and an outer sidewall 108 is formed on each of side surfaces of the gate electrode 104.

Next, as shown in FIG. 6B, n-type impurity ions are implanted into the semiconductor region 100x using the sidewalls 108A as a mask, to form n-type source/drain doped regions 109 in the semiconductor region 100x laterally outside the sidewalls 108A (i.e., the n-type source/drain doped regions 109 are adjacent to the respective remaining n-type extension doped regions 106 and extending laterally away from them). In this case, because an upper surface of the gate electrode 104 is covered with the cap film 105, the n-type impurity ions are not implanted into the gate electrode 104.

Next, as shown in FIG. 6C, carbon ions are implanted into the n-type source/drain doped regions 109 using the sidewalls 108A as a mask, to form carbon doped regions 110 in the n-type source/drain doped regions 109. In this case, because the upper surface of the gate electrode 104 is covered with the cap film 105, the carbon ions are not implanted into the gate electrode 104. Thus, the cap film 105 plays a role in reducing or preventing implantation into the gate electrode 104 of carbon ions which would reach and penetrate the gate insulating film 103.

Next, as shown in FIG. 6D, by a thermal treatment, the n-type impurity contained in the n-type extension doped regions 106 is activated to form n-type extension regions 111, while the n-type impurity contained in the n-type source/drain doped regions 109 is activated to form n-type source/drain regions 112. Meanwhile, the carbon doped regions 110 are crystallized to form silicon mixed crystal layers 113 which are a silicon carbon layer.

Next, the cap film 105 is removed to expose the upper surface of the gate electrode 104. Thereafter, a first silicide layer is formed on the gate electrode 104, while second silicide layers are formed on the silicon mixed crystal layers 113.

Next, a process similar to that of manufacturing a typical semiconductor device including a MIS transistor is performed.

Thus, the conventional semiconductor device is manufactured.

Here, in general, silicon carbon has a smaller lattice constant than that of silicon. For example, when the solid solubility of carbon in silicon is 1%, the lattice constant of silicon carbon is reduced by about 0.4% compared to the lattice constant of silicon. Therefore, conventionally, the silicon mixed crystal layers 113 can apply a tensile stress in the gate length direction of the channel region, whereby the mobility of electrons can be increased, resulting in an improvement in the drive capability of the N-type MIS transistor.

### SUMMARY

However, methods for manufacturing conventional semiconductor devices have the following problem. The problem will be described with reference to FIGS. 7A and 7B. FIGS. 7A and 7B are cross-sectional views along the gate length for describing main steps in a method for manufacturing a conventional semiconductor device, indicating the problem with conventional semiconductor devices.

In the method for manufacturing the conventional semiconductor device, as shown in FIG. 7A, when the cap film 105 is removed after the aforementioned steps of FIGS. 6A-6D are successively performed, the inner sidewall (silicon oxide film) 107 and the isolation region (silicon oxide film) 101, which are made of the same material as that of the cap film (silicon oxide film) 105, are also removed, so that an end surface of the inner sidewall 107 is moved to a position farther inside than a side surface of the outer sidewall 108, i.e., a trench Te is formed. Meanwhile, an upper surface of the isolation region 101 is moved to a position lower than an upper surface of the n-type source/drain region 112, i.e., a trench Ts is formed.

Therefore, as shown in FIG. 7B, when first and second silicide layers 114 and 115 are formed after removal of the cap film 105, an end of the second silicide layer 115 reaches a position below the outer sidewall 108 (see Se). Therefore, the second silicide layer 115 comes into the proximity of the junction surface of the n-type extension region 111, and therefore, junction leakage occurs in the n-type extension region 111. In addition, the other end of the second silicide layer 115 extends in a depth direction (see Ss). Therefore, the second silicide layer 115 comes into the proximity of the junction surface of the n-type source/drain region 112, and therefore, junction leakage occurs in the n-type source/drain region 112.

Thus, conventionally, there is the problem that, due to removal of the cap film 105, the second silicide layer 115 is formed so that one end of thereof comes to a position below the outer sidewall 108 while the other end extends in the depth direction, and therefore, the second silicide layer 115 cannot be formed with high accuracy.

Here, if carbon ions are implanted into the gate electrode 104 in the absence of the cap film 105, the carbon ions penetrate the gate insulating film 103, so that a silicon mixed crystal layer is formed which penetrates the gate insulating film 103, and therefore, the formation of a silicon mixed crystal layer in the gate electrode 104 cannot be controlled. Therefore, conventionally, the cap film 105 needs to be formed, and as a result, the cap film 105 needs to be removed. Thus, there is the problem that the second silicide layer 115 cannot be formed with high accuracy.

In view of the aforementioned problem, the detailed description describes implementations of a technique of controlling formation of a silicon mixed crystal layer in a gate electrode, thereby forming a silicide layer with high accuracy without forming a cap film.

An example semiconductor device includes a gate insulating film formed on a semiconductor region of a first conductivity type, a gate electrode formed on the gate insulating film and including a polysilicon film of a second conductivity type and a first silicon mixed crystal layer formed on the polysilicon film, a first silicide layer formed on the first silicon mixed crystal layer, impurity diffused regions of the second conductivity type formed in the semiconductor region laterally outside the gate electrode, second silicon mixed crystal layers containing carbon formed in upper regions of the impurity diffused regions, and second silicide layers formed on the second silicon mixed crystal layers.

In the example semiconductor device, because the formation of the first silicon mixed crystal layer in the gate electrode can be controlled, the formation of a cap film which is required in the conventional art is no longer required. Therefore, it is possible to reduce or avoid the formation of a silicide layer one end of which comes into the proximity of the junction surface of the impurity diffused region, which is caused by removal of the cap film as in the conventional art. Therefore, the second silicide layers can be formed with high accuracy, whereby the occurrence of junction leakage can be reduced or prevented in the impurity diffused regions.

Moreover, the second silicon mixed crystal layers can apply a tensile stress in a gate length direction of a channel region of the semiconductor region, whereby the drive capability of the MIS transistor can be improved.

In the example semiconductor device, an upper region of the polysilicon film preferably has a larger average grain size than that of a lower region of the polysilicon film.

In this case, the gate electrode including the polysilicon film the lower region and the upper region having a larger average grain size than that of the lower region, and the first silicon mixed crystal layer can apply a tensile stress in the gate length direction of the channel region of the semiconductor region, whereby the drive capability of the MIS transistor can be improved.

In the example semiconductor device, an upper region of the polysilicon film preferably has a higher concentration of an impurity of the second conductivity type than that of a lower region of the polysilicon film.

In the example semiconductor device, the first and second silicon mixed crystal layers are each preferably a silicon carbon layer.

In the example semiconductor device, the second silicon mixed crystal layers preferably cause a tensile stress in the gate length direction of the channel region of the semiconductor region.

In the example semiconductor device, the gate electrode preferably causes a tensile stress in the gate length direction of the channel region of the semiconductor region.

In the example semiconductor device, the concentration of carbon atoms contained in the second silicon mixed crystal layer is preferably at least 0.5% or more.

In the example semiconductor device, the first conductivity type is preferably P type, and the second conductivity type is preferably N type.

The example semiconductor device preferably further includes sidewalls formed on side surfaces of the gate electrode. The impurity diffused regions are preferably source/drain regions formed in the semiconductor region laterally outside the sidewalls.

In this case, it is possible to reduce or avoid the formation of a silicide layer one end of which comes into the proximity of the junction surface of the source/drain region, which is caused by removal of a cap film as in the conventional art. Therefore, the second silicide layers can be formed with high accuracy, whereby the occurrence of junction leakage can be reduced or prevented in the source/drain regions.

In the example semiconductor device, the impurity diffused regions are preferably extension regions. The semiconductor device preferably further includes sidewalls formed on side surfaces of the gate electrode, and source/drain regions of the second conductivity type formed in the semiconductor region laterally outside the sidewalls. The second silicon mixed crystal layers are preferably formed extending in upper regions of the source/drain regions. The second silicide layers are preferably formed on the second silicon mixed crystal layers laterally outside the sidewalls.

In this case, it is possible to reduce or avoid the formation of a silicide layer one end of which is moved to a position below the outer sidewall, and the other end of which extends in the depth direction (i.e., a silicide layer one end of which comes into the proximity of the junction surface of the extension region, and the other end which comes into the proximity of the junction surface of the source/drain region), which is caused by removal of a cap film as in the conventional art. Therefore, the second silicide layers can be formed with high accuracy, whereby the occurrence of junction leakage can be reduced or prevented in the extension regions and the source/drain regions.

The example semiconductor device preferably further includes sidewall stress films formed on side surfaces of the gate electrode. The sidewalls are preferably formed on the side surfaces of the gate electrode with the sidewall stress films being interposed therebetween.

An example method for manufacturing a semiconductor device includes the steps of (a) forming a gate insulating film on a semiconductor region of a first conductivity type, (b) forming a polysilicon film in the shape of a gate electrode on the gate insulating film, (c) forming impurity diffused regions of a second conductivity type in the semiconductor region laterally outside the polysilicon film, and a first silicon mixed crystal layer containing carbon on the polysilicon film, and forming second silicon mixed crystal layers containing carbon in upper regions of the impurity diffused regions, and (d) forming a first silicide layer on the first silicon mixed crystal layer, and second silicide layers on the second silicon mixed crystal layers. The gate electrode includes the polysilicon film and the first silicon mixed crystal layer formed on the polysilicon film.

In the example method, because the formation of the first silicon mixed crystal layer in the gate electrode can be controlled, the formation of a cap film which is required in the conventional art is no longer required. Therefore, it is possible to reduce or avoid the formation of a silicide layer one end of which comes into the proximity of the junction surface of the impurity diffused region, which is caused by removal of the cap film as in the conventional art. Therefore, the second silicide layers can be formed with high accuracy, whereby the occurrence of junction leakage can be reduced or prevented in the impurity diffused regions.

Moreover, the second silicon mixed crystal layers can apply a tensile stress in a gate length direction of a channel region of the semiconductor region, whereby the drive capability of the MIS transistor can be improved.

In the example method, step (c) preferably includes the steps of (c1) forming a first impurity doped region of the second conductivity type in an upper region of the polysilicon film, and second impurity doped regions of the second conductivity type in the semiconductor region laterally outside the polysilicon film, (c2) forming a first carbon doped region in an upper region of the first impurity doped region, and second carbon doped regions in upper regions of the second impurity doped regions, and (c3) after step (c2), performing a thermal treatment with respect to the semiconductor region to form the impurity diffused regions from the second impurity doped regions, the first silicon mixed crystal layer from the first carbon doped region, and the second silicon mixed crystal layers from the second carbon doped regions.

In this case, the first carbon doped region can be formed in the amorphized region of the first impurity doped region, whereby the formation of the first carbon doped region penetrating the gate insulating film is reduced or prevented. Therefore, the formation of the first silicon mixed crystal layer in the gate electrode can be controlled.

In the example method, in step (c1), at least a portion of each of the first impurity doped region and the second impurity doped regions is preferably amorphized. In step (c2), the first carbon doped region is preferably formed in the amorphized region of the first impurity doped region, and the second carbon doped regions are formed in the amorphized regions of the second impurity doped regions.

The example method preferably further includes the steps of (e) after step (c2) and before step (c3), forming, on an entire surface of the semiconductor region, a stress film which causes a tensile stress in a gate length direction of a channel region of the semiconductor region, and (f) after step (c3) and before step (d), removing the stress film. Step (c3) preferably includes the step of performing the thermal treatment while the stress film is applying a tensile stress to the polysilicon film in which the first impurity doped region is formed.

In this case, it is possible to recrystallize the amorphized region of the polysilicon film in which the first impurity doped region is formed, to form an upper region thereof having a larger average grain size than that of a lower region thereof. As a result, the gate electrode including the polysilicon film having the lower and upper regions, and the first silicon mixed crystal layer can apply a tensile stress in the gate length direction of the channel region of the semiconductor region, whereby the drive capability of the MIS transistor can be improved.

The example method preferably further includes the steps of (e) after step (c2) and before step (c3), forming, on an entire surface of the semiconductor region, a stress film which causes a tensile stress in a gate length direction of a channel region of the semiconductor region, and (f) after step (c3) and before step (d), forming sidewall stress films from the stress film, on side surfaces of the gate electrode. Step (c3) preferably includes the step of performing the thermal treatment while the stress film is applying a tensile stress to the polysilicon film in which the first impurity doped region is formed.

In this case, it is possible to recrystallize the amorphized region of the polysilicon film in which the first impurity doped region is formed, to form an upper region thereof having a larger average grain size than that of a lower region thereof. As a result, the gate electrode including the polysilicon film having the lower and upper regions, and the first silicon mixed crystal layer can apply a tensile stress in the gate length direction of the channel region of the semiconductor region, whereby the drive capability of the MIS transistor can be improved.

In the example method, in step (c3), an upper region which is obtained by recrystallizing the amorphized region of the polysilicon film in which the first impurity doped region is formed preferably has a higher average grain size than that of a lower region which is a non-amorphized region of the polysilicon film in which the first impurity doped region is formed.

According to the semiconductor device of the present disclosure and the method for manufacturing the semiconductor device, the first carbon doped region can be formed in the amorphized region of the first impurity doped region, whereby the formation of the first carbon doped region penetrating the gate insulating film can be reduced or prevented. As a result, the formation of the first silicon mixed crystal layer in the gate electrode can be controlled, and therefore, the formation of a cap film which is required in the conventional art is no longer required. Therefore, it is possible to reduce or avoid the formation of a silicide layer one end of which comes into the proximity of the junction surface of the impurity diffused region, which is caused by removal of the cap film as in the conventional art. Therefore, the second silicide layers can be formed with high accuracy, whereby the occurrence of junction leakage can be reduced or prevented in the impurity diffused regions.

Moreover, the second silicon mixed crystal layers can apply a tensile stress in the gate length direction of the channel region of the semiconductor region, whereby the drive capability of the MIS transistor can be improved.

### BRIEF DESCRIPTION OF THE DRAWINGS

FIGS. 1A-1C are cross-sectional views along the gate length for describing main steps in a method for manufacturing a semiconductor device according to a first embodiment of the present disclosure in the order in which the semiconductor device is manufactured.

FIGS. 2A-2C are cross-sectional views along the gate length for describing main steps in the method for manufacturing the semiconductor device of the first embodiment of the present disclosure in the order in which the semiconductor device is manufactured.

FIG. 3 is a graph showing a relationship between implantation energies and implantation depths for each of carbon ions, arsenic ions, and C₁₆H₁₀ molecular ions.

FIGS. 4A-4C are cross-sectional views along the gate length for describing main steps in a method for manufacturing a semiconductor device according to a second embodiment of the present disclosure in the order in which the semiconductor device is manufactured.

FIGS. 5A-5C are cross-sectional views along the gate length for describing main steps in the method for manufacturing the semiconductor device of the second embodiment of the present disclosure in the order in which the semiconductor device is manufactured.

FIGS. 6A-6D are cross-sectional views along the gate length for describing main steps in a method for manufacturing a conventional semiconductor device in the order in which the semiconductor device is manufactured.

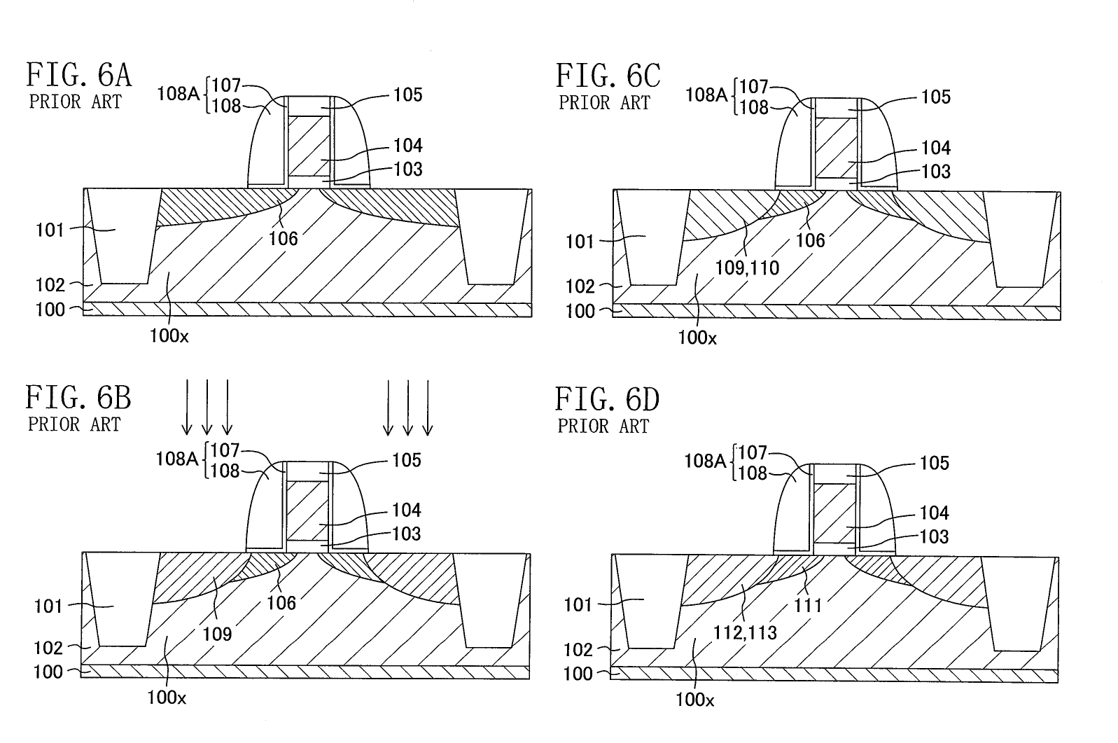

FIGS. 7A and 7B are cross-sectional views along the gate length for describing main steps in a method for manufacturing a conventional semiconductor device, indicating a problem with conventional semiconductor devices.

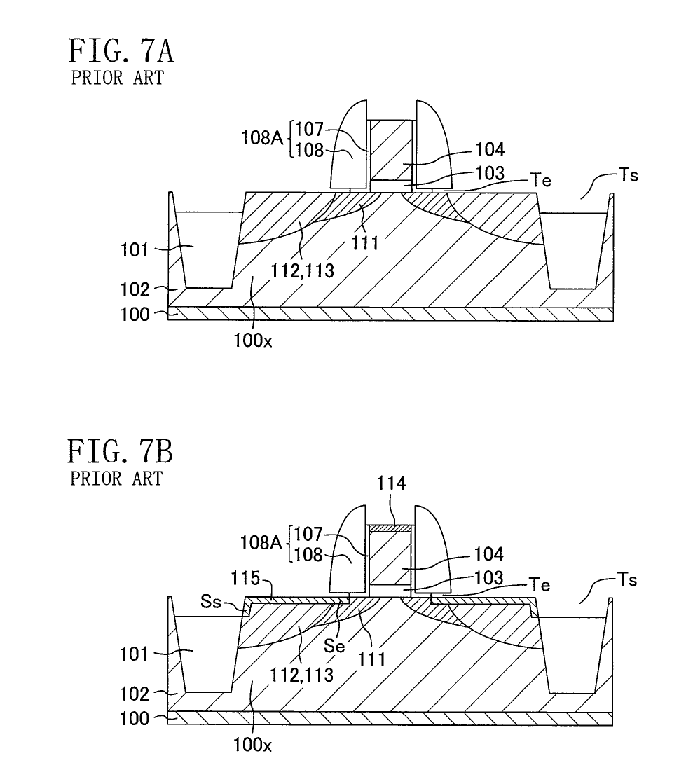

### DETAILED DESCRIPTION

Embodiments of the present disclosure will be described hereinafter with reference to the accompanying drawings.

### First Embodiment

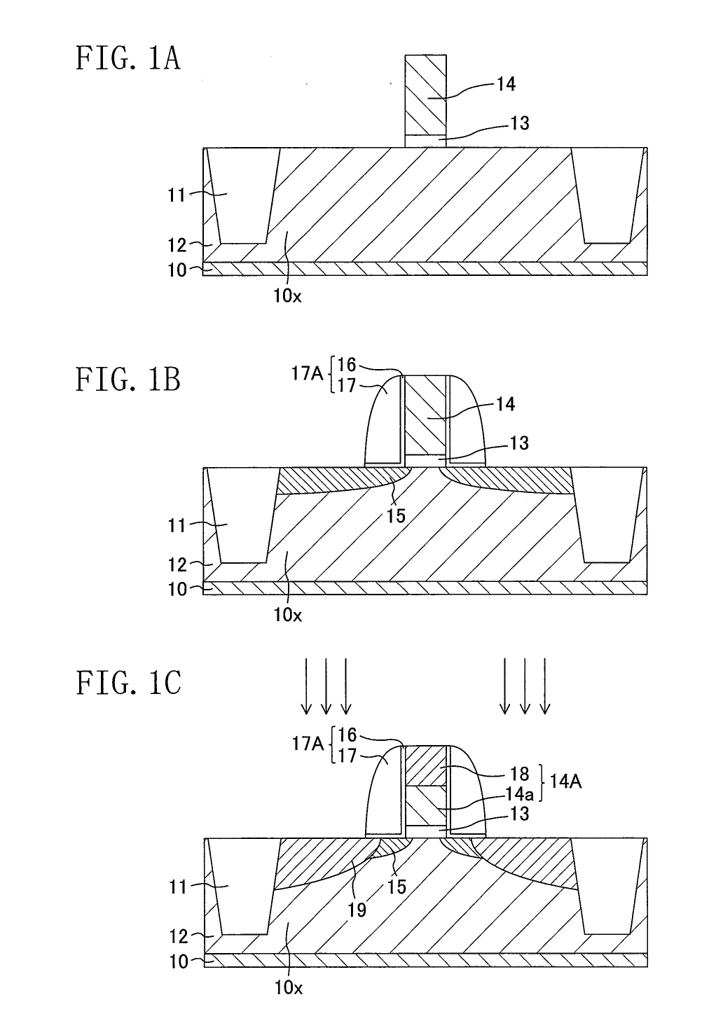

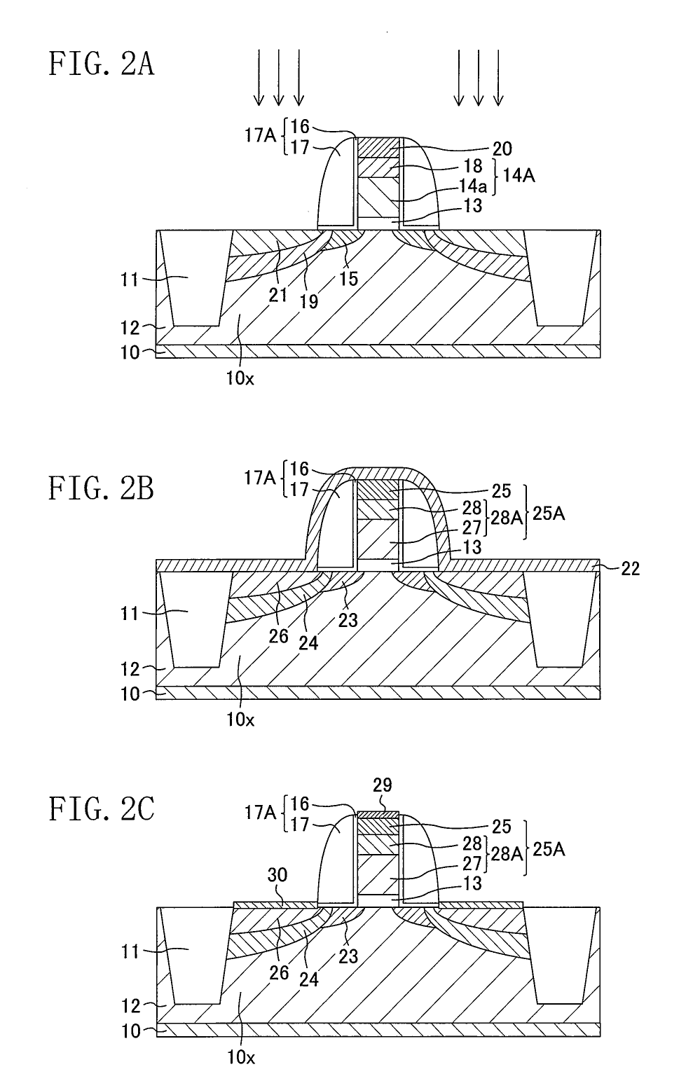

A method for manufacturing a semiconductor device according to a first embodiment of the present disclosure will be described hereinafter with reference to FIGS. 1A-1C and 2A-2C. FIGS. 1A-2C are cross-sectional views along the gate length for describing main steps in a method for manufacturing the semiconductor device of the first embodiment of the present disclosure in the order in which the semiconductor device is manufactured.

Initially, as shown in FIG. 1A, an isolation region 11 which is a trench in which, for example, a silicon oxide film is embedded, is formed in an upper portion of a semiconductor substrate 10 made of, for example, silicon by, for example, shallow trench isolation (STI). As a result, a semiconductor region 10x which is surrounded by the isolation region 11 is formed in the semiconductor substrate 10. Thereafter, p-type impurity ions, such as boron (B) or the like, are implanted into the semiconductor substrate 10 by ion implantation, and thereafter, a thermal treatment is performed, to form a p-type well region 12 in the semiconductor substrate 10.

Thereafter, a gate insulating film formation film which is, for example, a silicon oxide film having a thickness of 2.0 nm is deposited on the semiconductor region 10x by, for example, chemical vapor deposition (CVD). Thereafter, for example, a polysilicon film having a thickness of 100 nm is deposited on the gate insulating film formation film by, for example, CVD.

Thereafter, a resist (not shown) having the shape of a gate electrode is formed on the polysilicon film by lithography, and thereafter, the polysilicon film and the gate insulating film formation film are successively patterned by dry etching using the resist as a mask. As a result, a gate insulating film 13 is formed on the semiconductor region 10x, while a polysilicon film 14 having the gate electrode shape is formed on the gate insulating film 13.

Next, as shown in FIG. 1B, n-type impurity ions, such as arsenic (As) or the like, are implanted into the semiconductor region 10x by ion implantation using the polysilicon film 14 as a mask. As a result, n-type extension doped regions 15 having a relatively shallow junction depth are formed, in a self-aligned manner, in the semiconductor region 10x laterally outside the polysilicon film 14.

Thereafter, for example, a silicon oxide film having a thickness of 10 nm and a silicon nitride film having a thickness of 30 nm are successively deposited on an entire surface of the semiconductor region 10x by, for example, CVD, and are then subjected to anisotropic etching. As a result, a sidewall 17A including an inner sidewall 16 made of the silicon oxide film having an L-shaped cross-section, and an outer sidewall 17 made of the silicon nitride film, is formed on each of side surfaces of the polysilicon film 14.

Next, as shown in FIG. 1C, n-type impurity ions, such as As or the like, are implanted into the polysilicon film 14 and the semiconductor region 10x by ion implantation using the sidewalls 17A as a mask, where, for example, the implantation energy is 10 keV, and the implantation dose is 2.5×10¹⁵ cm⁻². As a result, an n-type first impurity doped region 18 is formed in an upper region of the polysilicon film 14, while n-type source/drain doped regions (n-type second impurity doped regions) 19 having a relatively deep junction depth are formed, in a self-aligned manner, in the semiconductor region 10x laterally outside the sidewalls 17A. In this case, due to the implantation of the n-type impurity ions into the polysilicon film 14, at least a portion of a region (i.e., the n-type first impurity doped region 18) of the polysilicon film 14 in which the n-type impurity ions are implanted is amorphized. Meanwhile, due to the implantation of the n-type impurity ions into the semiconductor region 10x, at least a portion of each of regions (i.e., the n-type source/drain doped regions (n-type second impurity doped regions) 19) of the semiconductor region 10x in which the n-type impurity ions are implanted is amorphized.

Thus, in this embodiment, the n-type impurity ions are implanted into the polysilicon film 14 as well as the semiconductor region 10x, without providing a cap film covering the upper surface of the polysilicon film 14, to form the n-type first impurity doped region 18 as well as the n-type source/drain doped regions (n-type second impurity doped regions) 19. As a result, a polysilicon film 14A including a polysilicon film 14a and the n-type first impurity doped region 18 is formed, while the n-type source/drain doped regions (n-type second impurity doped regions) 19 are formed. Meanwhile, an amorphized region is formed in at least a portion of each of the n-type first and second impurity doped regions 18 and 19. Note that the amorphized regions of the n-type first and second impurity doped regions 18 and 19 are formed in upper regions of the n-type first and second impurity doped regions 18 and 19, respectively. However, because it is difficult to clearly show where the amorphized regions are formed, the amorphized regions are not shown in FIG. 1C.

Next, as shown in FIG. 2A, molecular ions containing carbon, such as, specifically, C₁₆H₁₀ molecular ions or the like, are implanted into the amorphized region of the n-type first impurity doped region 18 and the amorphized regions of the n-type source/drain doped regions (n-type second impurity doped regions) 19, by ion implantation, where, for example, the implantation energy is 2 keV, and the implantation dose is 2.5×10¹⁵ cm⁻². As a result, a first carbon doped region 20 is formed in an upper region of the n-type first impurity doped region 18, while second carbon doped regions 21 are formed in upper regions of the n-type source/drain doped regions (n-type second impurity doped regions) 19. In this case, the first carbon doped region 20 is formed in the amorphized region of the n-type first impurity doped region 18, and is not formed outside the amorphized region. The second carbon doped regions 21 are formed in the amorphized regions of the n-type source/drain doped regions (n-type second impurity doped regions) 19, and are not formed outside the amorphized regions.

Here, when the same ion is implanted into a crystalline region and an amorphous region under the same ion implantation conditions, the amorphous region is more difficult to implant the ion than the crystalline region, and therefore, the implantation depth of an ion doped region formed in the amorphous region can be caused to be shallower than the implantation depth of an ion doped region formed in the crystalline region. Moreover, here, in general, molecular ions containing carbon are heavier than carbon ions, and therefore, when molecular ions containing carbon and carbon ions are implanted into the same region under the same ion implantation conditions, the implantation depth of the region into which the molecular ions containing carbon are implanted can be caused to be shallower than the implantation depth of the region into which the carbon ions are implanted. Therefore, in this embodiment, molecular ions containing carbon (i.e., ions heavier than carbon ions) instead of carbon ions are implanted into an amorphous region (i.e., a region more difficult to implant ions than a crystalline region) instead of a crystalline region.

Specifically, in this embodiment, as shown in FIG. 2A, molecular ions containing carbon are implanted into the amorphized region of the n-type first impurity doped region 18. As a result, the first carbon doped region 20 can be formed in the amorphized region of the n-type first impurity doped region 18, whereby it is possible to reduce or prevent entrance to the polysilicon film 14a below the n-type first impurity doped region 18 and penetration of the gate insulating film 13, of the molecular ions containing carbon implanted in the n-type first impurity doped region 18.

Next, as shown in FIG. 2B, a stress film 22 which is, for example, a silicon nitride film having a tensile stress of 1 GPa and having a thickness of 50 nm, and causes a tensile stress in the gate length direction of the channel region of the semiconductor region 10x, is deposited on an entire surface of the semiconductor region 10x by, for example, CVD.

Thereafter, a thermal treatment is performed at 650° C. for one minute, for example. The thermal treatment activates the n-type impurity contained in the n-type extension doped regions 15 to form n-type extension regions 23 from the n-type extension doped regions 15, and at the same time, activates the n-type impurity contained in the n-type source/drain doped regions 19 to form n-type source/drain regions (n-type impurity diffused regions) 24 from the n-type source/drain doped regions (n-type second impurity doped regions) 19.

The thermal treatment also crystallizes the first and second carbon doped regions 20 and 21 to form a first silicon mixed crystal layer 25 from the first carbon doped region 20, and second silicon mixed crystal layers 26 from the second carbon doped regions 21.

Because the thermal treatment is performed while the stress film 22 is applying a tensile stress to the polysilicon film 14A in which the n-type first impurity doped region 18 is formed, the thermal treatment also recrystallizes the amorphized region of the polysilicon film 14A to form an upper region 28 including a polysilicon film which has a larger average grain size than that of a polysilicon film of a lower region 27. Thus, the upper region 28 which is formed by recrystallizing the amorphized region of the polysilicon film 14A has a larger average grain size than that of the lower region 27 which is the non-amorphized region of the polysilicon film 14A.

The thermal treatment also activates and causes the n-type impurity contained in the n-type first impurity doped region 18 to diffuse into the polysilicon film 14a below the n-type first impurity doped region 18.

Thus, a gate electrode 25A is formed which includes an n-type polysilicon film 28A which includes the lower region 27 and the upper region 28 having a larger average grain size than that of the lower region 27, and the first silicon mixed crystal layer 25 which is a silicon carbon layer formed on the n-type polysilicon film 28A and containing carbon atoms at a concentration of, for example, 1% (i.e., 0.5% or more). Meanwhile, the second silicon mixed crystal layers 26 which are a silicon carbon layer containing carbon atoms at a concentration of, for example, 1% (i.e., 0.5% or more), are formed in upper regions of the n-type source/drain regions 24. Here, although the thermal treatment causes the n-type impurity in the n-type first impurity doped region 18 to diffuse into the polysilicon film 14a, it is difficult to cause the n-type impurity contained in the n-type first impurity doped region 18 to uniformly diffuse into the polysilicon film 14a. Therefore, the n-type impurity concentration of the n-type polysilicon film 28A is not uniform, and the n-type impurity concentration is higher in an upper region of the n-type polysilicon film 28A than in a lower region of the n-type polysilicon film 28A.

Thus, in this embodiment, the following two processes are combined: a thermal treatment is performed to crystallize the regions (i.e., the second carbon doped regions 21) which are formed by implanting the molecular ions containing carbon into the amorphized regions of the n-type source/drain doped regions (n-type second impurity doped regions) 19, thereby forming the second silicon mixed crystal layers 26 containing carbon; and a thermal treatment is performed while the stress film 22 is formed on the amorphized region of the n-type first impurity doped region 18, to recrystallize the amorphized region of the n-type first impurity doped region 18, thereby forming the upper region 28 having a larger average grain size than that of the lower region 27, i.e., a stress memorization technique (SMT).

Next, as shown in FIG. 2C, after the stress film 22 is removed, a natural oxide film (not shown) formed on surfaces of the first silicon mixed crystal layer 25 and the second silicon mixed crystal layers 26 is removed. Thereafter, a silicidation metal film (not shown) made of, for example, nickel (Ni) having a thickness of 10 nm is deposited on an entire surface of the semiconductor region 10x by, for example, sputtering. Thereafter, by a first rapid thermal annealing (RTA) treatment, Si in the first and second silicon mixed crystal layers 25 and 26 and Ni in the silicidation metal film are caused to react with each other, thereby forming a first silicide layer 29 made of nickel silicide having a thickness of 15 nm on the first silicon mixed crystal layer 25, and second silicide layers 30 made of nickel silicide having a thickness of 15 nm on the second silicon mixed crystal layers 26.

Thereafter, the resultant arrangement is immersed in an etchant to remove an unreacted silicidation metal film remaining on the isolation region 11, the sidewalls 17A, and the like. Thereafter, a second RTA treatment is performed at a temperature higher than that of the first RTA treatment to stabilize the silicide composition ratios of the first and second silicide layers 29 and 30.

Next, steps similar to those of manufacturing a typical semiconductor device including a MIS transistor are successively performed. Specifically, for example, a step of forming contact plugs connected to the first and second silicide layers 29 and 30 in an interlayer insulating film formed on the semiconductor substrate 10, a step of forming interconnections connected to the contact plugs on the interlayer insulating film, and the like are successively performed.

Thus, the semiconductor device of this embodiment can be manufactured.

A structure of the semiconductor device of the first embodiment of the present disclosure will be described hereinafter with reference to FIG. 2C.

As shown in FIG. 2C, the semiconductor device of this embodiment includes the semiconductor region 10x of the semiconductor substrate 10 surrounded by the isolation region 11, the gate insulating film 13 formed on the semiconductor region 10x, the gate electrode 25A formed on the gate insulating film 13 and including the n-type polysilicon film 28A and the first silicon mixed crystal layer 25 formed on the n-type polysilicon film 28A, the sidewalls 17A formed on the side surfaces of the gate electrode 25A, the first silicide layer 29 formed on the first silicon mixed crystal layer 25, the n-type extension regions 23 formed in the semiconductor region 10x laterally outside the gate electrode 25A, the n-type source/drain regions (n-type impurity diffused regions) 24 formed in the semiconductor region 10x laterally outside the sidewalls 17A, the second silicon mixed crystal layers 26 formed in the upper regions of the n-type source/drain regions 24, and the second silicide layers 30 formed on the second silicon mixed crystal layers 26.

The upper region 28 of the n-type polysilicon film 28A has a larger average grain size than that of the lower region 27 of the n-type polysilicon film 28A. An upper region of the n-type polysilicon film 28A also has a higher n-type impurity concentration than that of a lower region of the n-type polysilicon film 28A.

The second silicon mixed crystal layers 26 cause a tensile stress in the gate length direction of the channel region of the semiconductor region 10x. The gate electrode 25A including the upper region 28 having a larger average grain size than that of the lower region 27, and the first silicon mixed crystal layer 25 also causes a tensile stress in the gate length direction of the channel region of the semiconductor region 10x. Note that the stress caused by the gate electrode 25A is the sum of a stress caused by the upper region 28 and a stress caused by the first silicon mixed crystal layer 25, and the proportion of the stress caused by the upper region 28 in the stress caused by the gate electrode 25A is larger than that of the stress caused by the first silicon mixed crystal layer 25.

According to this embodiment, as shown in FIG. 2A, by implanting molecular ions containing carbon into the amorphized region of the n-type first impurity doped region 18 of the polysilicon film 14A, the first carbon doped region 20 is formed in the amorphized region of the n-type first impurity doped region 18, whereby it is possible to reduce or prevent entrance into the polysilicon film 14a below the n-type first impurity doped region 18 and penetration through the gate insulating film 13 of the molecular ions containing carbon implanted in the n-type first impurity doped region 18 (i.e., formation of the first carbon doped region 20 penetrating the gate insulating film 13, or formation of the first silicon mixed crystal layer 25 penetrating the gate insulating film 13), and therefore, it is possible to control formation of the first silicon mixed crystal layer 25 in the gate electrode 25A. As a result, the formation of a cap film which is required in the conventional art is no longer required. Therefore, it is possible to reduce or avoid the formation of a silicide layer one end of which is moved to a position below the outer sidewall, and the other end of which extends in the depth direction (i.e., a silicide layer one end of which comes into the proximity of the junction surface of the n-type extension region, and the other end which comes into the proximity of the junction surface of the n-type source/drain region), which is caused by removal of the cap film as in the conventional art. Therefore, as shown in FIG. 2C, the second silicide layers 30 can be formed with high accuracy, whereby the occurrence of junction leakage can be reduced or prevented in the n-type extension regions 23 and the n-type source/drain regions (n-type impurity diffused regions) 24.

In addition, the second silicon mixed crystal layers 26 can apply a tensile stress in the gate length direction of the channel region of the semiconductor region 10x, whereby the drive capability of the N-type MIS transistor can be improved.

Moreover, the gate electrode 25A including the upper region 28 having a larger average grain size than that of the lower region 27, and the first silicon mixed crystal layer 25 can apply a tensile stress in the gate length direction of the channel region of the semiconductor region 10x, whereby the drive capability of the N-type MIS transistor can be further improved.

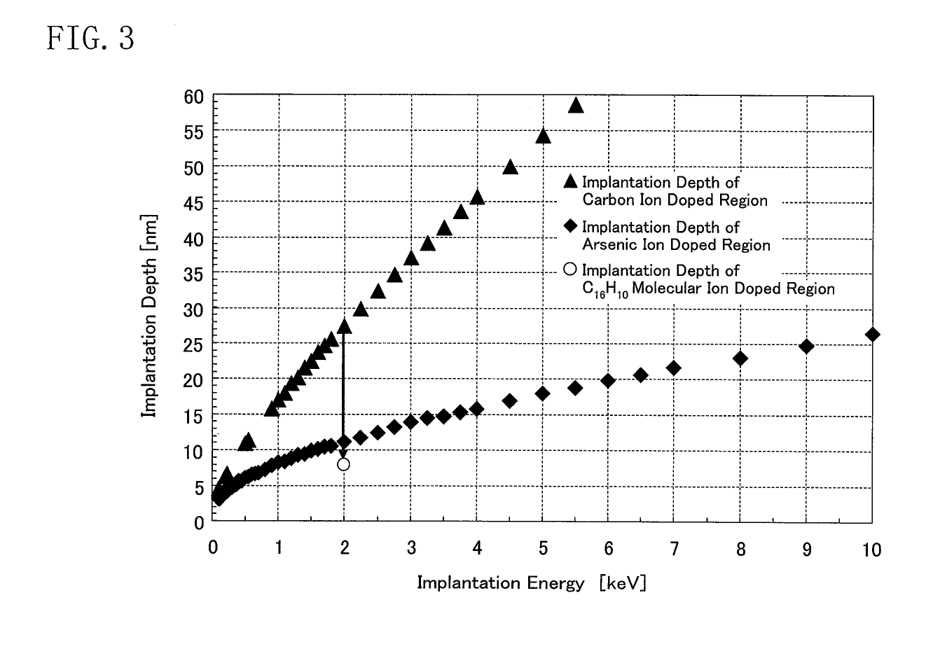

Here, C₁₆H₁₀ molecular ions will be described with reference to FIG. 3 in order to effectively describe advantages of the present disclosure. FIG. 3 is a graph showing a relationship between implantation energies (keV) and implantation depths (nm) for each of carbon ions (C ions), arsenic ions (As ions), and C₁₆H₁₀ molecular ions.

Measurement of FIG. 3 was conducted as follows. Implantation depths of a C ion doped region and an As ion doped region were measured when C ions and As ions were implanted into a polysilicon region while varying the implantation energy, where the implantation dose was 2.5×10¹⁵ cm⁻². On the other hand, implantation depths of a C₁₆H₁₀ molecular ion doped region were measured when C₁₆H₁₀ molecular ions were implanted into an amorphous silicon region while varying the implantation energy, where the implantation dose was 2.5×10¹⁵ cm⁻².

As shown in FIG. 3, for example, when C₁₆H₁₀ molecular ions were implanted into the amorphous silicon region at an implantation energy of 2 keV, the implantation depth of the C₁₆H₁₀ molecular ion doped region was 10 nm or less. In contrast to this, as shown in FIG. 3, for example, when C ions were implanted into the polysilicon region at an implantation energy of 2 keV, the implantation depth of the C ion doped region was 25 nm or more. Thus, by implanting C₁₆H₁₀ molecular ions, which are heavier than C ions, into the amorphous silicon region, which is more difficult to implant ions than the polysilicon region, the implantation depth of the C₁₆H₁₀ molecular ion doped region can be caused to be shallower than the implantation depth of the C ion doped region.

### Second Embodiment

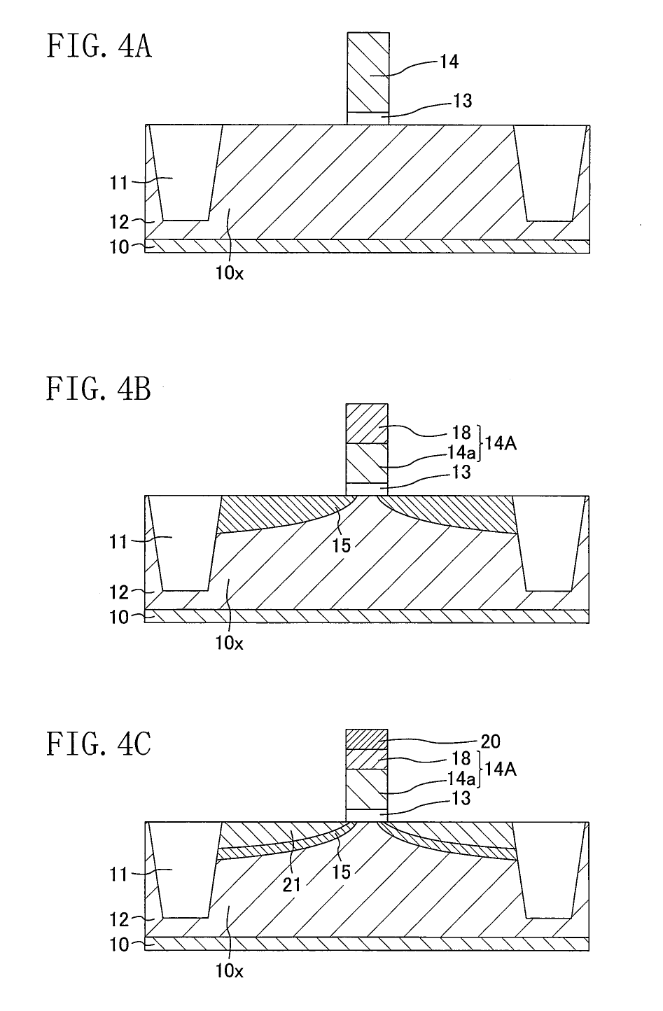

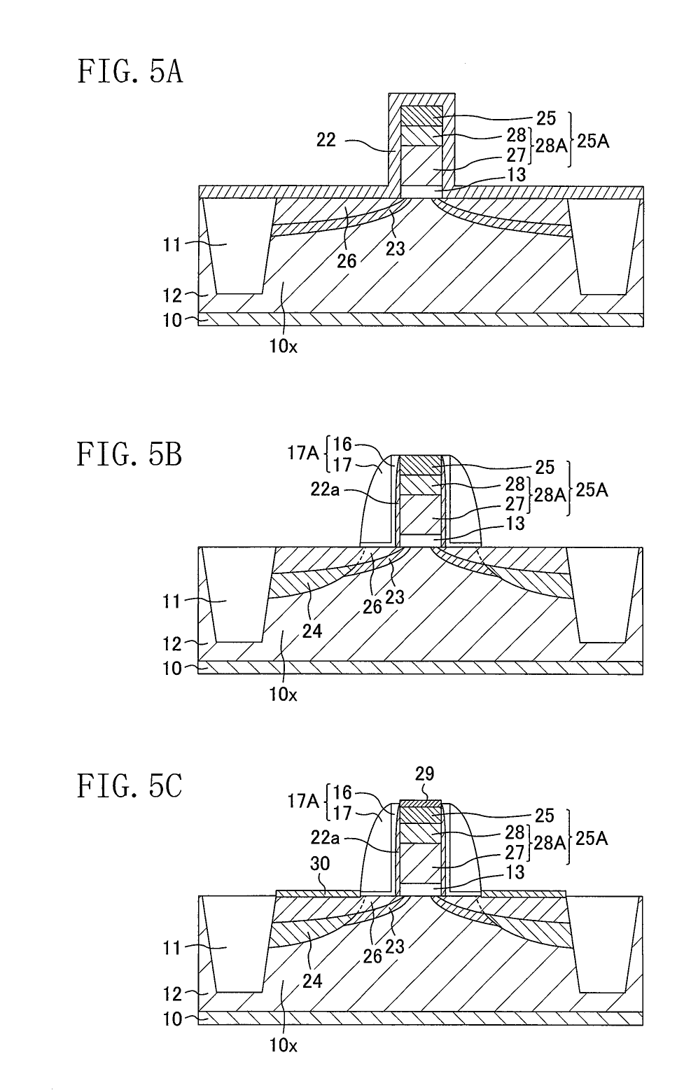

A method for manufacturing a semiconductor device according to a second embodiment of the present disclosure will be described hereinafter with reference to FIGS. 4A-4C and 5A-5C. FIGS. 4A-5C are cross-sectional views for describing main steps in a method for manufacturing the semiconductor device of the second embodiment of the present disclosure in the order in which the semiconductor device is manufactured. Note that, in FIG. 4A-5C, the same components as those of the first embodiment are indicated by the same reference characters in FIGS. 1A-2C of the first embodiment. Therefore, in this embodiment, differences from the first embodiment will be mainly described, and features common to the first and second embodiments will not be redundantly described.

Initially, the same step as that shown in FIG. 1A of the first embodiment is performed to obtain an arrangement shown in FIG. 4A (the same arrangement as that shown in FIG. 1A).

Next, as shown in FIG. 4B, n-type impurity ions, such as As or the like, are implanted into a polysilicon film 14 and a semiconductor region 10x by ion implantation using the polysilicon film 14 as a mask. As a result, an n-type first impurity doped region 18 is formed in an upper region of the polysilicon film 14, while n-type extension doped regions (n-type second impurity doped regions) 15 having a relatively shallow junction depth are formed in the semiconductor region 10x laterally outside the polysilicon film 14 in a self-aligned manner. In this case, by the implantation of the n-type impurity ions into the polysilicon film 14, at least a portion of a region (i.e., the n-type first impurity doped region 18) of the polysilicon film 14 in which the n-type impurity ions are implanted is amorphized. Meanwhile, by the implantation of the n-type impurity ions into the semiconductor region 10x, at least a portion of each of regions (i.e., the n-type extension doped region (n-type second impurity doped region) 15) of the semiconductor region 10x in which the n-type impurity ions are implanted is amorphized.

Thus, in this embodiment, the n-type impurity ions are implanted into the polysilicon film 14 as well as the semiconductor region 10x, without providing a cap film covering the upper surface of the polysilicon film 14, to form the n-type first impurity doped region 18 as well as the n-type extension doped regions (n-type second impurity doped regions) 15. Thus, a polysilicon film 14A including a polysilicon film 14a and the n-type first impurity doped region 18 is formed, while the n-type extension doped regions (n-type second impurity doped regions) 15 are formed. Meanwhile, an amorphized region is formed in at least a portion of each of the n-type first and second impurity doped regions 18 and 15. Note that the amorphized regions of the n-type first and second impurity doped regions 18 and 15 are formed in the upper regions of the n-type first and second impurity doped regions 18 and 15, respectively. However, because it is difficult to clearly show where the amorphized regions are formed, the amorphized regions are not shown in FIG. 4B.

Next, as shown in FIG. 4C, molecular ions containing carbon, such as, specifically, C₁₆H₁₀ molecular ions or the like, are implanted into the amorphized region of the n-type first impurity doped region 18 and the amorphized regions of the n-type extension doped regions (n-type second impurity doped regions) 15, by ion implantation, where, for example, the implantation energy is 2 keV, and the implantation dose is 2.5×10¹⁵ cm⁻². As a result, a first carbon doped region 20 is formed in an upper region of the n-type first impurity doped region 18, while second carbon doped regions 21 are formed in upper regions of the n-type extension doped regions (n-type second impurity doped regions) 15. In this case, the first carbon doped region 20 is formed in the amorphized region of the n-type first impurity doped region 18, and is not formed outside the amorphized region. The second carbon doped regions 21 are formed in the amorphized regions of the n-type extension doped regions (n-type second impurity doped regions) 15, and are not formed outside the amorphized regions.

Next, as shown in FIG. 5A, a stress film 22 which is, for example, a silicon nitride film having a tensile stress of 1 GPa and having a thickness of 50 nm, and causes a tensile stress in the gate length direction of the channel region of the semiconductor region 10x, is deposited on an entire surface of the semiconductor region 10x by, for example, CVD.

Thereafter, a thermal treatment is performed at 650° C. for one minute, for example. The thermal treatment activates the n-type impurity contained in the n-type extension doped regions 15 to form n-type extension regions 23 from the n-type extension doped regions 15.

The thermal treatment also crystallizes the first and second carbon doped regions 20 and 21 to form a first silicon mixed crystal layer 25 from the first carbon doped region 20, and second silicon mixed crystal layers 26 from the second carbon doped regions 21.

Because the thermal treatment is performed while the stress film 22 is applying a tensile stress to the polysilicon film 14A in which the n-type first impurity doped region 18 is formed, the thermal treatment also recrystallizes the amorphized region of the polysilicon film 14A to form an upper region 28 including a polysilicon film which has a larger average grain size than that of a polysilicon film of a lower region 27. Thus, the upper region 28 which is formed by recrystallizing the amorphized region of the polysilicon film 14A has a larger average grain size than that of the lower region 27 which is the non-amorphized region of the polysilicon film 14A.

The thermal treatment also activates the n-type impurity contained in the n-type first impurity doped region 18 to cause the n-type impurity contained in the n-type first impurity doped region 18 to diffuse into the polysilicon film 14a below the n-type first impurity doped region 18.

Thus, a gate electrode 25A is formed which includes an n-type polysilicon film 28A which includes the lower region 27 and the upper region 28 having a larger average grain size than that of the lower region 27, and the first silicon mixed crystal layer 25 which is a silicon carbon layer formed on the n-type polysilicon film 28A and containing carbon atoms at a concentration of, for example, 1% (i.e., 0.5% or more). Meanwhile, the second silicon mixed crystal layers 26 which are a silicon carbon layer containing carbon atoms at a concentration of, for example, 1% (i.e., 0.5% or more), are formed in upper regions of the n-type extension regions 23.

Next, as shown in FIG. 5B, the stress film 22 is subjected to anisotropic dry etching to form a sidewall stress film 22a on each of side surfaces of the gate electrode 25A. Thereafter, for example, a silicon oxide film having a thickness of 10 nm and a silicon nitride film having a thickness of 30 nm are successively deposited on an entire surface of the semiconductor region 10x by, for example, CVD, and thereafter, the silicon oxide film and the silicon nitride film are subjected to anisotropic etching. As a result, a sidewall 17A including the inner sidewall 16 made of the silicon oxide film having an L-shaped cross-section and the outer sidewall 17 made of the silicon nitride film, is formed on each of the side surfaces of the gate electrode 25A with the sidewall stress film 22a being interposed therebetween.

Thereafter, n-type impurity ions, such as As or the like, are implanted into the semiconductor region 10x by ion implantation using the sidewalls 17A as a mask. As a result, n-type source/drain doped regions having a relatively deep junction depth are formed in the semiconductor region 10x laterally outside the sidewalls 17A in a self-aligned manner. Thereafter, a thermal treatment is performed to activate the n-type impurity contained in the n-type source/drain doped regions, thereby forming n-type source/drain regions 24 from the n-type source/drain doped regions.

Next, as shown in FIG. 5C, a natural oxide film (not shown) formed on a surface of the first silicon mixed crystal layer 25, and on surfaces of the second silicon mixed crystal layers 26 laterally outside the sidewalls 17A, is removed. Thereafter, a silicidation metal film (not shown) made of, for example, Ni having a thickness of 10 nm is deposited on an entire surface of the semiconductor region 10x by, for example, sputtering. Thereafter, by a first rapid thermal annealing (RTA) treatment, Si in the first and second silicon mixed crystal layers 25 and 26 and Ni in the silicidation metal film are caused to react with each other, thereby forming a first silicide layer 29 made of nickel silicide having a thickness of 15 nm on the first silicon mixed crystal layer 25, and second silicide layers 30 made of nickel silicide having a thickness of 15 nm on the second silicon mixed crystal layers 26 laterally outside the sidewalls 17A.

Thereafter, the resultant arrangement is immersed in an etchant to remove an unreacted silicidation metal film remaining on the isolation region 11, the sidewalls 17A, and the like. Thereafter, a second RTA treatment is performed at a temperature higher than that of the first RTA treatment to stabilize the silicide composition ratios of the first and second silicide layers 29 and 30.

Next, steps similar to those of manufacturing a typical semiconductor device including a MIS transistor are successively performed. Specifically, for example, a step of forming contact plugs connected to the first and second silicide layers 29 and 30 in an interlayer insulating film formed on the semiconductor substrate 10, a step of forming interconnections connected to the contact plugs on the interlayer insulating film, and the like are successively performed.

Thus, the semiconductor device of this embodiment can be manufactured.

Here, differences in between the manufacturing methods of the first embodiment and this embodiment are as follows.

In the first embodiment, after the sidewalls 17A of FIG. 1B are formed, the n-type first and second impurity doped regions 18 and 19 are formed as shown in FIG. 1C, and the first and second carbon doped regions 20 and 21 are then formed as shown in FIG. 2A. Thereafter, as shown in FIG. 2B, the n-type source/drain regions 24 are formed from the n-type second impurity doped regions 19, the first and second silicon mixed crystal layers 25 and 26 are formed from the first and second carbon doped regions 20 and 21, and the upper region 28 is formed by recrystallizing the amorphized region of the n-type first impurity doped region 18.

In contrast to this, in the second embodiment, before formation of the sidewalls 17A of FIG. 5B, the n-type first and second impurity doped regions 18 and 15 are formed as shown in FIG. 4B, the first and second carbon doped regions 20 and 21 are then formed as shown in FIG. 4C, and as shown in FIG. 5A, the n-type extension regions 23 are then formed from the n-type second impurity doped regions 15, the first and second silicon mixed crystal layers 25 and 26 are then formed from the first and second carbon doped regions 20 and 21, and the upper region 28 is then formed by recrystallizing the amorphized region of the n-type first impurity doped region 18.

Thus, in the first embodiment, the second carbon doped regions 21 are provided in the upper regions of the n-type source/drain doped regions 19 before the second silicon mixed crystal layers 26 are formed from the second carbon doped regions 21. In the second embodiment, the second carbon doped regions 21 are provided in the upper regions of the n-type extension doped regions 15 before the second silicon mixed crystal layers 26 are formed from the second carbon doped regions 21.

A structure of the semiconductor device of the second embodiment of the present disclosure will be described hereinafter with reference to FIG. 5C.

As shown in FIG. 5C, the semiconductor device of this embodiment includes the semiconductor region 10x of the semiconductor substrate 10 surrounded by the isolation region 11, the gate insulating film 13 formed on the semiconductor region 10x, the gate electrode 25A formed on the gate insulating film 13 and including the n-type polysilicon film 28A and the first silicon mixed crystal layer 25 formed on the n-type polysilicon film 28A, the sidewall stress films 22a formed on the side surfaces of the gate electrode 25A, the sidewalls 17A formed on the side surfaces of the gate electrode 25A with the sidewall stress films 22a being interposed therebetween, the first silicide layer 29 formed on the first silicon mixed crystal layer 25, the n-type extension regions (n-type impurity diffused regions) 23 formed in the semiconductor region 10x laterally outside the gate electrode 25A, the n-type source/drain regions 24 formed in the semiconductor region 10x laterally outside the sidewalls 17A, the second silicon mixed crystal layers 26 formed extending from upper regions of the n-type extension regions 23 to upper regions of the n-type source/drain regions 24, and the second silicide layers 30 formed on the second silicon mixed crystal layers 26 laterally outside the sidewalls 17A.

The upper region 28 of the n-type polysilicon film 28A has a larger average grain size than that of the lower region 27 of the n-type polysilicon film 28A. An upper region of the n-type polysilicon film 28A has a higher n-type impurity concentration than that of a lower region of the n-type polysilicon film 28A.

The second silicon mixed crystal layers 26 cause a tensile stress in the gate length direction of the channel region of the semiconductor region 10x. The gate electrode 25A including the upper region 28 having a larger average grain size than that of the lower region 27, and the first silicon mixed crystal layer 25 also causes a tensile stress in the gate length direction of the channel region of the semiconductor region 10x.

Here, differences between the structures of the first and second embodiments are as follows.

In the first embodiment, as shown in FIG. 2C, the second silicon mixed crystal layers 26 are formed in the upper regions of the n-type source/drain regions 24. By contrast, in the second embodiment, as shown in FIG. 5C, the second silicon mixed crystal layers 26 are formed extending from the upper regions of the n-type extension region 23 to the upper regions of the n-type source/drain regions 24. Moreover, in the first embodiment, the sidewalls 17A directly contact the side surfaces of the gate electrode 25A. By contrast, in the second embodiment, the sidewalls 17A are formed on the side surfaces of the gate electrode 25A with the sidewall stress films 22a being interposed therebetween.

According to the second embodiment, as shown in FIG. 4C, by implanting molecular ions containing carbon into the amorphized region of the n-type first impurity doped region 18 of the polysilicon film 14A, the first carbon doped region 20 is formed in the amorphized region of the n-type first impurity doped region 18, whereby it is possible to reduce or prevent entrance into the polysilicon film 14a below the n-type first impurity doped region 18 and penetration through the gate insulating film 13 of the molecular ions containing carbon implanted into the n-type first impurity doped region 18 (i.e., formation of the first carbon doped region 20 penetrating the gate insulating film 13, or formation of the first silicon mixed crystal layer 25 penetrating the gate insulating film 13), and therefore, it is possible to control formation of the first silicon mixed crystal layer 25 in the gate electrode 25A. As a result, the formation of a cap film which is required in the conventional art is no longer required. Therefore, it is possible to reduce or avoid the formation of a silicide layer one end of which is moved to a position below the outer sidewall, and the other end of which extends in the depth direction (i.e., a silicide layer one end of which comes into the proximity of the junction surface of the n-type extension region, and the other end of which comes into the proximity of the junction surface of the n-type source/drain region), due to removal of the cap film, as in the conventional art. Therefore, as shown in FIG. 5C, the second silicide layer 30 can be formed with high accuracy, whereby the occurrence of junction leakage can be reduced or prevented in the n-type extension regions (n-type impurity diffused regions) 23 and the n-type source/drain regions 24.

In addition, the second silicon mixed crystal layers 26 can apply a tensile stress in the gate length direction of the channel region of the semiconductor region 10x, whereby the drive capability of the N-type MIS transistor can be improved.

Moreover, the gate electrode 25A including the upper region 28 having a larger average grain size than that of the lower region 27, and the first silicon mixed crystal layer 25 can apply a tensile stress in the gate length direction of the channel region of the semiconductor region 10x, whereby the drive capability of the N-type MIS transistor can be further improved.

Moreover, as shown in FIG. 5B, the stress film 22 is not completely removed, leaving the sidewall stress films 22a which are the stress film 22 on the side surfaces of the gate electrode 25A, whereby it is possible to reduce or avoid the difficulty in removing portions of the stress film 22 formed on the side surfaces of the gate electrode 25A.

Note that, in the second embodiment, as shown in FIG. 5B, a specific example has been described in which the stress film 22 is subjected to anisotropic dry etching to form the sidewall stress films 22a on the side surfaces of the gate electrode 25A before the sidewalls 17A are formed on the side surfaces of the gate electrode 25A with the sidewall stress films 22a being interposed therebetween, i.e., the sidewall stress films 22a are provided between the gate electrode 25A and the sidewalls 17A. The present disclosure is not limited to this. For example, a stress film may be completely removed before a sidewall may be formed directly on each of side surfaces of a gate electrode.

Moreover, in the second embodiment, a specific example has been described in which, as shown in FIG. 5B, after formation of the n-type source/drain doped regions, the n-type source/drain regions 24 are formed from the n-type source/drain doped regions by a thermal treatment, and the first and second silicide layers 29 and 30 are then formed as shown in FIG. 5C. The present disclosure is not limited to this. For example, after formation of the n-type source/drain doped regions, C₁₆H₁₀ molecular ions may be implanted into amorphized regions of the n-type source/drain doped regions as in the first embodiment, and a thermal treatment may be then performed to form silicon mixed crystal layers from the regions in which the C₁₆H₁₀ molecular ions are implanted, and n-type source/drain regions from the n-type source/drain doped regions, and thereafter, first and second silicide layers may be formed. In this case, the silicon mixed crystal layers newly provided in upper regions of the n-type source/drain regions can apply a tensile stress in the gate length direction of the channel region of the semiconductor region, whereby the drive capability of the N-type MIS transistor can be further improved than in the second embodiment.

Note that, in the first and second embodiments, a specific example has been described in which the n-type polysilicon film 28A is formed directly on the gate insulating film 13, i.e., the gate electrode 25A includes the n-type polysilicon film 28A and the first silicon mixed crystal layer 25. The present disclosure is not limited to this. For example, a metal film may be provided between the gate insulating film and the n-type polysilicon film, i.e., a gate electrode may include a metal film, an n-type polysilicon film, and a first silicon mixed crystal layer. Also in this case, advantages similar to those of the first and second embodiments can be obtained. Here, the metal film may be specifically made of, for example, titanium nitride (TiN), tantalum nitride (TaN), or the like.

Moreover, in the first and second embodiments, a specific example has been described in which C₁₆H₁₀ molecular ions are used as molecular ions containing carbon contained in the first carbon doped region 20. The present disclosure is not limited to this. Instead of C₁₆H₁₀ molecular ions, for example, covalent cluster ions such as Cx (x≧2) or the like, hydrogen bond cluster ions, or the like may be employed.

Moreover, in the first and second embodiments, a specific example has been described in which a silicon carbon layer is used as the second silicon mixed crystal layer 26. The present disclosure is not limited to this. As the second silicon mixed crystal layer, any layer that can cause a tensile stress in the gate length direction of the channel region of the semiconductor region 10x may be employed.

Moreover, in the first and second embodiments, a specific example has been described in which a silicon oxide film is used as the gate insulating film 13. The present disclosure is not limited to this. Instead of silicon oxide films, a silicon oxynitride film (SiON film), a high-k film, or the like may be used.

In the present disclosure, because the formation of a silicon mixed crystal layer in a gate electrode is controlled, the formation of a cap film is not required. Therefore, the present disclosure is useful for semiconductor devices having silicon mixed crystal layers in source/drain regions (or extension regions and source/drain regions), and methods for manufacturing the semiconductor devices.

What is claimed is:

1. A semiconductor device comprising:
a gate insulating film formed on a semiconductor region of a first conductivity type;
a gate electrode formed on the gate insulating film and including a polysilicon film of a second conductivity type and a first silicon mixed crystal layer formed on the polysilicon film;
a first silicide layer formed on the first silicon mixed crystal layer;
impurity diffused regions of the second conductivity type formed in the semiconductor region laterally outside the gate electrode;
second silicon mixed crystal layers containing carbon formed in upper regions of the impurity diffused regions; and
second silicide layers formed on the second silicon mixed crystal layers.

2. The semiconductor device of claim 1, wherein
an upper region of the polysilicon film has a larger average grain size than that of a lower region of the polysilicon film.

3. The semiconductor device of claim 1, wherein
an upper region of the polysilicon film has a higher concentration of an impurity of the second conductivity type than that of a lower region of the polysilicon film.

4. The semiconductor device of claim 1, wherein
the first and second silicon mixed crystal layers are each a silicon carbon layer.

5. The semiconductor device of claim 1, wherein
the second silicon mixed crystal layers cause a tensile stress in a gate length direction of a channel region of the semiconductor region.

6. The semiconductor device of claim 1, wherein
the gate electrode causes a tensile stress in a gate length direction of a channel region of the semiconductor region.

7. The semiconductor device of claim 1, wherein
the concentration of carbon atoms contained in the second silicon mixed crystal layer is at least 0.5% or more.

8. The semiconductor device of claim 1, wherein
the first conductivity type is P type, and
the second conductivity type is N type.

9. The semiconductor device of claim 1, further comprising:
sidewalls formed on side surfaces of the gate electrode, wherein
the impurity diffused regions are source/drain regions formed in the semiconductor region laterally outside the sidewalls.

10. The semiconductor device of claim 1, wherein
the impurity diffused regions are extension regions,
the semiconductor device further includes
sidewalls formed on side surfaces of the gate electrode, and
source/drain regions of the second conductivity type formed in the semiconductor region laterally outside the sidewalls,
the second silicon mixed crystal layers are formed extending in upper regions of the source/drain regions, and
the second silicide layers are formed on the second silicon mixed crystal layers laterally outside the sidewalls.

11. The semiconductor device of claim 10, further comprising:
sidewall stress films formed on side surfaces of the gate electrode, wherein
the sidewalls are formed on the side surfaces of the gate electrode with the sidewall stress films being interposed therebetween.

12. A method for manufacturing a semiconductor device, comprising the steps of:
(a) forming a gate insulating film on a semiconductor region of a first conductivity type;
(b) forming a polysilicon film in the shape of a gate electrode on the gate insulating film;
(c) forming impurity diffused regions of a second conductivity type in the semiconductor region laterally outside the polysilicon film, and a first silicon mixed crystal layer containing carbon on the polysilicon film, and forming second silicon mixed crystal layers containing carbon in upper regions of the impurity diffused regions; and
(d) forming a first silicide layer on the first silicon mixed crystal layer, and second silicide layers on the second silicon mixed crystal layers,
wherein
the gate electrode includes the polysilicon film and the first silicon mixed crystal layer formed on the polysilicon film.

13. The method of claim 12, wherein
step (c) includes the steps of
(c1) forming a first impurity doped region of the second conductivity type in an upper region of the polysilicon film, and second impurity doped regions of the second conductivity type in the semiconductor region laterally outside the polysilicon film,
(c2) forming a first carbon doped region in an upper region of the first impurity doped region, and second carbon doped regions in upper regions of the second impurity doped regions, and
(c3) after step (c2), performing a thermal treatment with respect to the semiconductor region to form the impurity diffused regions from the second impurity doped regions, the first silicon mixed crystal layer from the first carbon doped region, and the second silicon mixed crystal layers from the second carbon doped regions.

14. The method of claim 13, wherein
in step (c1), at least a portion of each of the first impurity doped region and the second impurity doped regions is amorphized, and
in step (c2), the first carbon doped region is formed in the amorphized region of the first impurity doped region, and the second carbon doped regions are formed in the amorphized regions of the second impurity doped regions.

15. The method of claim 14, further comprising the steps of:
(e) after step (c2) and before step (c3), forming, on an entire surface of the semiconductor region, a stress film which causes a tensile stress in a gate length direction of a channel region of the semiconductor region; and
(f) after step (c3) and before step (d), removing the stress film,
wherein
step (c3) includes the step of performing the thermal treatment while the stress film is applying a tensile stress to the polysilicon film in which the first impurity doped region is formed.

16. The method of claim 14, further comprising the steps of:
(e) after step (c2) and before step (c3), forming, on an entire surface of the semiconductor region, a stress film which causes a tensile stress in a gate length direction of a channel region of the semiconductor region; and
(f) after step (c3) and before step (d), forming sidewall stress films from the stress film, on side surfaces of the gate electrode,
wherein
step (c3) includes the step of performing the thermal treatment while the stress film is applying a tensile stress to the polysilicon film in which the first impurity doped region is formed.

17. The method of claim 15, wherein
in step (c3), an upper region which is obtained by recrystallizing the amorphized region of the polysilicon film in which the first impurity doped region is formed has a higher average grain size than that of a lower region which is a non-amorphized region of the polysilicon film in which the first impurity doped region is formed.

18. The method of claim 16, wherein
in step (c3), an upper region which is obtained by recrystallizing the amorphized region of the polysilicon film in which the first impurity doped region is formed has a higher average grain size than that of a lower region which is a non-amorphized region of the polysilicon film in which the first impurity doped region is formed.
